(19) United States
(12) Patent Application Publication
(10) Pub. No.: US 2005/0281948 A1
(43) Pub. Date: Dec. 22, 2005

(54) Vaporizing temperature sensitive materials

(75) Inventors: Jeremy M. Grace, Penfield, NY (US); Michael Long, Hilton, NY (US); Bruce E. Koppe, Caledonia, NY (US)

Correspondence Address: Pamela R. Crocker;Patent Legal Staff, Eastman Kodak Company, 343 State Street, Rochester, NY, 14650-2201, US

(73) Assignee: Eastman Kodak Company

(21) Appl. No.: 10/870,623

(22) Filed: Jun. 17, 2004

(51) Int. Cl. C23C 16/00; B05D 3/00

(52) U.S. Cl. 427/248.1; 427/561

(57) ABSTRACT

A method for vaporizing material onto a substrate surface to form a film includes providing a quantity of material into a vaporization apparatus, heating the material in the vaporization apparatus at a first temperature condition, and applying a heat pulse which acts on a portion of the material to cause such portion of the material to vaporize and be applied to the substrate surface.

### CROSS REFERENCE TO RELATED APPLICATIONS

Reference is made to commonly assigned U.S. patent application Ser. No. 10/352,558 filed Jan. 28, 2003 by Jeremy M. Grace et al., entitled “Method of Designing a Thermal Physical Vapor Deposition System”, and commonly assigned U.S. patent application Ser. No. 10/784,585 filed Feb. 23, 2004 by Michael Long et al., entitled “Device and Method for Vaporizing Temperature Sensitive Materials”, the disclosures of which are herein incorporated by reference.

### FIELD OF THE INVENTION

The present invention relates to the field of physical vapor deposition where a source material is heated to a temperature so as to cause vaporization and produce a vapor plume to form a thin film on a surface of a substrate.

### BACKGROUND OF THE INVENTION

An OLED device includes a substrate, an anode, a hole-transporting layer made of an organic compound, an organic luminescent layer with suitable dopants, an organic electron-transporting layer, and a cathode. OLED devices are attractive because of their low driving voltage, high luminance, wide-angle viewing and capability for full-color flat emission displays. Tang et al. described this multilayer OLED device in their U.S. Pat. Nos. 4,769,292 and 4,885,211.

Physical vapor deposition in a vacuum environment is the principal way of depositing thin organic material films as used in small molecule OLED devices. Such methods are well known, for example, in Barr U.S. Pat. No. 2,447,789 and Tanabe et al. EP 0 982 411. The organic materials used in the making of OLED devices are often subject to degradation when maintained at or near the desired rate-dependent vaporization temperature for extended periods of time. Exposure of sensitive organic materials to higher temperatures can cause changes in the structure of the molecules and associated changes in material properties.

To overcome the thermal sensitivity of these materials, only small quantities of organic materials have been loaded in sources, and they are heated as little as possible. In this manner, the material is consumed before it has reached the temperature exposure threshold to cause significant degradation. The limitations with this practice are that the available vaporization rate is very low due to the limitation on heater temperature, and the operation time of the source is very short due to the small quantity of material present in the source. The low deposition rate and frequent source recharging place substantial limitations on the throughput of OLED manufacturing facilities.

A secondary consequence of heating the entire organic material charge to roughly the same temperature is that it is impractical to mix additional organic materials, such as dopants, with a host material unless the vaporization behavior and vapor pressure of the dopant is very close to that of the host material. This is generally not the case and, as a result, prior art devices frequently require the use of separate sources to codeposit host and dopant materials.

Obtaining the desired film composition from a mixture of materials by thermal evaporation has also been discussed in the prior art pertaining to semiconductor devices. U.S. Pat. No. 3,607,135 to Gereth et al. disclose flash evaporation in combination with a guide funnel and tube feed mechanism to solve the problem of maintaining film composition from a mixture of As and Ga, which have significantly disparate vapor pressure curves. Continuous operation is achieved by advancing powder through a tube by use of a threaded piston arrangement. The tube delivers powder to a vibrating trough, which feeds material to the guide funnel and into the flash evaporation zone. Care is taken to control relative temperatures of the flash evaporation zone and the surfaces of the guide funnel and feed tube assembly so as to avoid occlusion of the feed mechanism during the course of operation. U.S. Pat. No. 3,990,894 to Kinoshita et al. discloses the use of several thermal deposition sources in succession having differing material compositions to compensate for the drift in composition resulting from the disparate vapor pressure curves of Se and Te in making a thin film of a specific Se-Te alloy. Japanese Publication 06-161137 to Naoyuki et al. discloses the use of a conveyor belt feed mechanism and flash evaporation to deposit pure Se and alloys of Se/Te and Se/As. In their disclosure, the material delivered by conveyor belt is a coarse particulate with particle sizes in the range of 1-2 mm.

Other disclosed uses of flash evaporation techniques include deposition of oxide buffer layers, metal thin film resistors, generation of superfine particles, deposition of polymer layers and multilayers, and mixtures of OLED materials to form a white emitting device. U.S. Pat. No. 5,453,306 to Tatsumi et al. discloses the use of carrier gas to deliver powder to a plasma torch for depositing oxide buffer layers. U.S. Pat. No. 4,226,899 to Thiel et al. discloses the use of continuous wire feed in combination with flash evaporation to deposit thin film resistors having the desired temperature coefficient of resistance. U.S. Pat. No. 6,040,017 to Mikhael et al. discloses flash evaporation of atomized polymer liquids to produce polymer multilayers. U.S. Pat. No. 6,268,695 to Affinito mentions flash evaporation as a possible technique in depositing polymer-oxide multilayers for barrier materials for OLED devices. Japanese Publication 09-219289 to Kenji et al. discloses the use of flash evaporation to deposit white emitting OLED devices from mixed powder components. While some of these disclosures discuss the use of powders, none teaches a method for delivering a powder or weakly cohesive solid at constant rate to the flash evaporation source and none discusses a suitable way to compensate for nonuniform delivery rate in a powder feed mechanism.

For deposition on stationary substrates, a limiting factor for control of coating thickness is the degree of constancy of the material feed rate. Even if thickness monitoring techniques are used, if the deposition rate is not suitably stable, it can be difficult to achieve the desired end point thickness. Techniques based on vibration, such as that disclosed in U.S. Pat. No. 3,607,135, have a fair probability of suffering nonuniformity of feed rate from agglomeration of material in the feed path, which can either cause blockage and loss of rate or can cause uneven vapor delivery rate, as particles of highly varying size enter the flash evaporation zone in uncontrolled manner. Similarly, a technique in which powders drop from conveyor belts (Japanese Publication 06-161137) has a fair probability of suffering nonuniformity of feed rate for small particles, which can tend to adhere to the conveyor belt to some uncontrolled degree and thus cause variation in the rate at which material drops into the flash evaporation zone.

As with other powder feed-based techniques, control of composition can be accomplished by mixing the materials to be deposited prior to introducing them to the feed mechanism. Alternatively, because the approach of commonly assigned U.S. patent application Ser. No. 10/784,585 filed Feb. 23, 2004 by Michael Long et al., entitled “Device and Method for Vaporizing Temperature Sensitive Materials”, the disclosure of which is herein incorporated by reference, lends itself to small areas for the flash evaporation zone, multiple single-component sources can be arranged to vaporize material into a heated manifold. Control of their relative rates (through material feed rate and heater temperature) permits one to control the composition of the deposited film over a broad range. While commonly assigned U.S. patent application Ser. No. 10/784,585 discloses a superior method for delivering material at uniform rate in controllable fashion, for precise control of delivery rate, the challenge still remains that a column of powder or a weakly bound solid must be delivered to a flash evaporation zone with extremely uniform material feed rate.

Coating large-area substrates (i.e., in excess of 20 cm×20 cm) presents the additional challenge of maintaining a constant substrate velocity over the deposition zone. The combination of requiring constant substrate velocity and constant material feed rate present significant engineering challenges for large-area coatings by flash evaporation. In addition, multiple component films must be deposited with equally effective control of material feed rates of all components in order to obtain repeatable compositions or constant composition throughout the film.

### SUMMARY OF THE INVENTION

It is therefore an object of the present invention to provide a way whereby highly uniform thickness coatings can be obtained.

It is a further object of the present invention to provide a way to deposit one or more materials from the same source with extremely precise control over the relative amounts of each material in the deposited coating.

These objects are achieved by a method for vaporizing material onto a substrate surface to form a film, comprising:
a) providing a quantity of material into a vaporization apparatus;
b) heating the material in the vaporization apparatus at a first temperature condition; and
c) applying a heat pulse which acts on a portion of the material to cause such portion of the material to vaporize and be applied to the substrate surface.

### Advantages

It is an advantage of the present invention that it overcomes the need to have extremely uniform and constant material feed rate and substrate motion during deposition. In addition, the present invention overcomes heating and volume limitations of prior art devices in that only a small portion of material is heated to the desired rate-dependent vaporization temperature at a controlled rate. It is therefore a feature of the present invention to maintain a steady state time-varying vaporization process with a large charge of material, with pulsed heater temperature in synchronization with stepwise motion of the substrate. The present invention thus permits extended operation of the source with substantially reduced risk of degrading even very temperature sensitive materials. This feature additionally permits materials having different vaporization rates and degradation temperature thresholds to be co-sublimated in the same source.

It is another advantage of the present invention that it permits finer rate control through pulse height (also referred to as pulse amplitude) or pulse width modulation of the heater current. The same fine control via the heat pulse shape can be used to precisely meter dopant materials in combination with host materials by situating them in the same delivery manifold and pulsing them separately to control the relative amounts delivered to the substrate.

It is still another advantage of the present invention that it can be cooled and reheated in a matter of seconds to stop and reinitiate vaporization and achieve a steady vaporization rate quickly. This feature reduces contamination of the deposition chamber walls and conserves the materials when a substrate is not being coated.

It is a further advantage that the present device achieves substantially higher vaporization rates than in prior art devices without material degradation.

It is a still further advantage of the present invention that it can provide a vapor source in any orientation, which is not possible with prior art devices.

### BRIEF DESCRIPTION OF THE DRAWINGS

FIG. 1 is a cross-sectional schematic representation of a flash evaporation source indicating the various parameters used to model the source response to a flash evaporation pulse;

FIG. 2 shows an example of modeled evaporant (i.e., material to be deposited) surface temperature and manifold pressure in the source of FIG. 1 as a function of time in response to heat pulses;

FIG. 3 shows the required off time t_{off} for complete decay of vapor pressure pulses as a function of cooling time constant τ_{c} modeled for the source of FIG. 1;

FIG. 4A and FIG. 4B show representative modeled evaporant (i.e., material to be deposited) surface temperature Tᵥ and manifold pressure as a function of time in response to heat pulses, for cooling time constant values of 1 s and 20 s, respectively. The modeled responses are from the set used to provide the data shown in FIG. 3;

FIG. 5 shows the required heat input Tₘₐₓ as a function of heating time constant τ_{H} such that the average pressure and hence rate is maintained for the source of FIG. 1;

FIG. 6A and FIG. 6B show representative modeled evaporant surface temperature Tᵥ and manifold pressure as a function of time in response to heat pulses, for heating time constant values of 0.1 s and 10 s, respectively. The modeled responses are from the set used to provide the data shown in FIG. 5;

FIG. 7 shows the required heat input Tₘₐₓ as a function of the base temperature T_{b} while maintaining average pressure and hence rate for the source of FIG. 1;

FIG. 8A and FIG. 8B show representative modeled evaporant surface temperature Tᵥ and manifold pressure as a function of time in response to heat pulses, for base temperature T_{b} values of 273 K and 423 K, respectively. The modeled responses are from the set used to provide the data shown in FIG. 7;

FIG. 9 shows the average pressure (and hence relative rate) as a function of the pulse duration tₚᵤₗₛₑ, modeled for the source of FIG. 1 and illustrates manipulation of deposition rate by pulse width control;

FIG. 10A and FIG. 10B show representative modeled evaporant surface temperature Tᵥ and manifold pressure as a function of time in response to heat pulses, for pulses duration tₚᵤₗₛₑ values of 1 s and 4 s, respectively. The modeled responses are from the set used to provide the data shown in FIG. 9;

FIG. 11 shows the average pressure (and hence relative rate) as a function of pulse heat input Tₘₐₓ modeled for the source of FIG. 1 and illustrates manipulation of deposition rate by pulse height (or pulse amplitude) control;

FIG. 12A and FIG. 12B show representative modeled evaporant surface temperature Tᵥ and manifold pressure as a function of time in response to heat pulses, for pulse heat inputs Tₘₐₓ values of 755 K and 890 K, respectively. The modeled responses are from the set used to provide the data shown in FIG. 11;

FIG. 13A, FIG. 13B, and FIG. 13C show representative modeled evaporant surface temperature Tᵥ and manifold pressure as a function of time in response to heat pulses, for evaporant surface area Aₛ=1 cm² and τ_{V}=80 s; As=0.01 cm² and τ_{V}=0.3 s; and Aₛ=0.01 cm² and τ_{V}=8 s, respectively;

FIG. 14 shows the required time between pulses t_{off} for complete decay of the pressure pulse as a function of the vapor time constant τᵥ and an evaporant surface area Aₛ of 0.01 cm² modeled for the source of FIG. 1;

FIG. 15A and FIG. 15B show schematic arrangements of sources to produce a uniform coating along the length of a substrate (schematic cross sectional view) and over a large substrate area (schematic top view), respectively;

FIG. 16 shows an array of elongated manifolds arranged to produce a uniform coating over a large substrate area;

FIG. 17A, FIG. 17B, and FIG. 17C show pulse height (pulse amplitude) controlled relative rates of host and dopant, pulse width control of relative rates of host and dopant, and alternate layers of two components, respectively;

FIG. 18 shows a schematic of a flash evaporation deposition system with synchronized heat pulses, substrate motion, and material feed;

FIG. 19 shows the representative geometry used to calculate the deposition uniformity for substrates moved stepwise through a coating zone;

FIG. 20 shows modeled thickness profiles for 1, 2, and 6 steps using the geometry shown in FIG. 19;

FIG. 21 shows the modeled nonuniformity as a function of number of steps for a line source and different source-substrate spacings and plume shape exponents for the geometry depicted in FIG. 19;

FIG. 22 shows the modeled nonuniformity as a function of number of steps for a point source and different source-substrate spacings and plume shape exponents for the geometry depicted in FIG. 19;

FIG. 23 shows a side cross section schematic of a flash evaporation source to produce vapor pulses by heat pulse control or heat pulse control in combination with material feed control; and

FIG. 24 is a side cross section of a layer structure used in making OLED devices.

### DETAILED DESCRIPTION OF THE INVENTION

In order to illustrate the benefits of the present invention two models were constructed. The first model calculates the time-dependent pressure inside a vaporization manifold in response to heat pulses applied to an evaporant (i.e., material to be deposited by vaporization). The second model calculates the coating uniformity along the direction of motion of a substrate moved in stepwise fashion across a deposition zone containing a source that emits a vapor plume of specified shape.

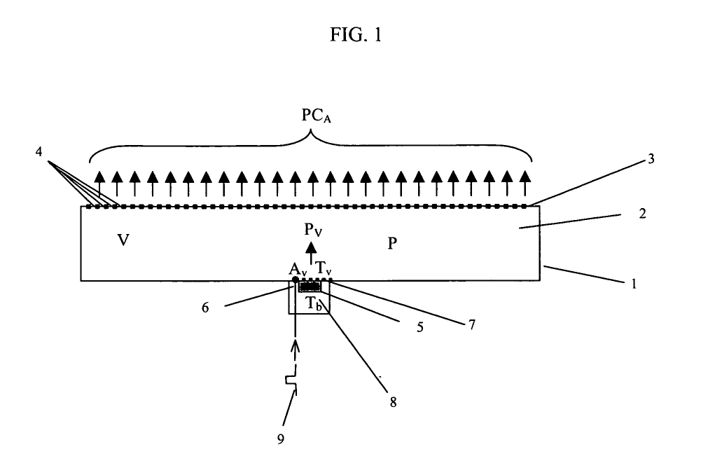

The source geometry and model parameters are shown in FIG. 1. The deposition source 1 comprises a heated manifold 2 having an exit surface 3 with an aperture 4 or plurality of apertures 4 having total conductance C_{A}. The evaporant 5 (i.e., material to be deposited, sublimate, material to be vaporized or sublimed) is located in a vaporization region 6 and is placed in contact with a heating element 7 on one surface, and is in contact with a region of lower temperature 8 on most of its remaining surface. The bulk of the evaporant is maintained at the lower temperature T_{b}, while the heating element 7 is used to bring the temperature of the contacted surface to a vaporization temperature Tᵥ.

The time required to establish Tᵥ depends on the heat input and the thermal contact of the material to the region held at T_{b}. Accordingly there are time constants of heating and cooling τ_{H} and τ_{C} associated with the time dependence of Tᵥ. The input power to the heating element 7 is expressed as a temperature Tₘₐₓ, which would be the steady state temperature of the evaporant surface in the absence of cooling other than by diffusion of heat from the evaporant surface through the evaporant and to the region of lower temperature. Using Newton's law of cooling, the rate of change of the evaporant surface temperature Tᵥ is given by:

$$\frac{{dT}_{v}}{dt} = \frac{( {T}_{maz} - {T}_{v} )}{{τ}_{H}} - \frac{( {T}_{v} - {T}_{b} )}{{τ}_{C}} . \qquad ( 1 )$$

The vaporization rate obtained by establishing the temperature Tᵥ at the evaporant surface having area Aᵥ is given by:

$$dP = \frac{{A}_{v}}{{V}_{m}} {P}_{v} \sqrt{\frac{{kT}_{v}}{2 π M}} dt , \qquad ( 2 )$$

where Vₘ is the volume of the manifold 2, k is the Boltzmann constant, M is the molecular mass of the evaporant material, and Pᵥ is the vapor pressure of the material. Because vaporization is a thermally activated process, the vapor pressure Pᵥ often has the form:

$${P}_{v} = {ⅇ}^{( a - \frac{b}{{T}_{v}} )} . \qquad ( 3 )$$

In addition to pressurization of the manifold by vaporization, there is loss of pressure to the area Aₛ driven by the actual pressure P within the manifold, as well as loss of pressure through the aperture(s) having a total conductance C_{A}. Thus, the net pressurization rate in the manifold is given by:

$$dP = [ \frac{{A}_{s}}{{V}_{m}} ( {P}_{v} - P ) \sqrt{\frac{{kT}_{v}}{2 π M}} - \frac{{C}_{A} P}{{V}_{m}} ] dt . \qquad ( 4 )$$

It is assumed the pressure outside the manifold is negligible (vacuum) and that the manifold walls are sufficiently hot so that no significant condensation occurs on them. The vapor time constant τᵥ=Vₘ/C_{A} can be used to express the aperture loss term in the above equation, as dP=−(P/τᵥ.)dt.

A heat pulse 9 applied to the heating element 7 has a pulse width tₚᵤₗₛₑ a pulse height Tₘₐₓ, and time between pulses t_{off}. When the pulse is on, the term Tₘₐₓ−Tᵥ in Eq. 1 applies. When the pulse is off, the heating term is set to zero and only the cooling term Tᵥ−T_{b} remains.

Starting with the initial condition P=0 and Tᵥ=T_{b}, the progression of Tᵥ and P can be computed by calculating dTᵥ (Eq. 1) and dP (Eq. 4 using Pᵥ from Eq. 3) for a given time step dt. The values of Tᵥ and P are then updated by adding respectively dTᵥ and dP, and another time step is taken. The process is iterated until the desired number of time steps has been completed. In the computation of dTᵥ the heat pulse shape is taken into account by dropping the heating term when the pulse is off and applying it when the heat pulse is on.

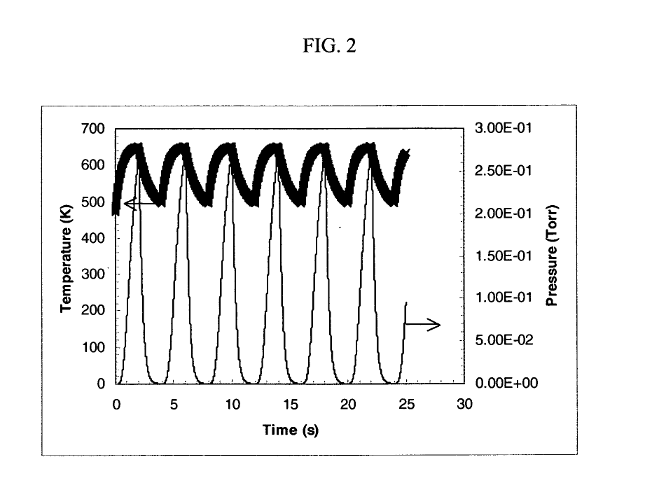

The end result is an array of values for P(t) and for Tᵥ(t). An example of calculated P(t) and Tᵥ(t) values is shown in FIG. 2 for aluminum tris-quinolate (Alq₃). In the calculations, the parameters were set to the following values: T_{b}=473.16 K, Tₘₐₓ=835 K, tₚᵤₗₛₑ=2 s, t_{off}=2 s, τ_{H}−1 s, τ_{C}=1 s, V=0.04 cm×0.04 cm×60 cm=9.6×10⁻⁴ m³, C_{A}=60×0.02 1/s=1.2×10⁻³ m³/s, Aₛ=1 cm×1 cm=1×10⁻⁴ m². (For the values for V and C_{A}, τ_{V}=0.8 s). The time step size was set to 5×10⁻³ s. As an approximation to the vapor pressure curve for Alq₃ the values a=24.706 1 n(Torr) and b=16743 K were used in Eq. 3. These parameters were obtained from a fit to vapor pressure measurements of Alq₃ using a Knudsen cell technique.

The time constants τ_{C}, τ_{H}, and τᵥ can be expected to determine the minimum time between pulses and hence the rate at which a deposition process can proceed. Applying the model of P(t) described above, one finds that a large value (i.e. slow response time) for τ_{H} can be overcome by using larger heat input (i.e. applying a higher value for Tₘₐₓ), without limiting the response time of Tᵥ and thus P. Furthermore, one finds that τᵥ becomes important only in the limit of very small surface area of evaporant exposed to Tᵥ. In addition, one finds that the effect of τ_{C} is substantially reduced because of the exponential dependence of Pᵥ on Tᵥ. Whereas a typical exponential decay requires a time of 5τ to reach practical completion, the decay of the effects of a pressure pulse Pᵥ reach practical completion in less than or on the order of τ_{C}, owing to the rapid decrease in Pᵥ with Tᵥ.

In order to illustrate these effects the model for P(t) was run with a “standard” set of parameters as a point of reference. Various parameters of primary interest were then changed, and the effects on the average manifold pressure P were assessed, or values of tₚᵤₗₛₑ, t_{off}, and or Tₘₐₓ were adjusted to give the same average pressure in the manifold with acceptable separation of pulses, and the required adjustments of these parameters were examined as a function of the parameter of primary interest.

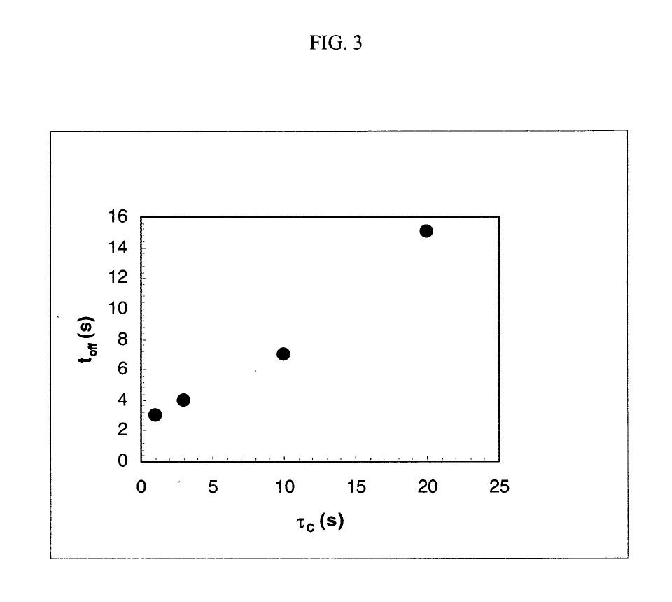

FIG. 3 illustrates the effects of τ_{c} on required delay time between pulses (t_{off}) to obtain similar manifold response. The data in FIG. 3 were computed with the following settings: T_{b}=373.16 K, τ_{H}=1 s, V=0.04 cm×0.04 cm×60 cm=9.6×10⁻⁴ m³, C_{A}=60×0.02 1/s=1.2×10⁻³ m³/s, Aₛ=1 cm×1 cm=1×10⁻⁴ m². (For the values for V and C_{A}, v=0.8 s). The time step size varied between 0.008 and 0.0175 s, depending on the choice of τ_{c}, such that a similar number of vapor pulses was obtained. Tₘₐₓ, tₚᵤₗₛₑ and t_{off} were adjusted to give similar time-averaged pressure and similar ratios of peak pressure to minimum pressure before the next pulse. The target average pressure was roughly 0.076 Torr, which corresponds to a deposition rate of roughly 50 A/s at a distance of 10 cm directly over the center of a source having the aperture conductance C_{A} indicated above. This estimate of rate is based on calculations described in commonly assigned U.S. patent application Ser. No. 10/352,558 filed Jan. 28, 2003 by Jeremy M. Grace et al., entitled “Method of Designing a Thermal Physical Vapor Deposition System”, the disclosure of which is herein incorporated by reference. As τ_{c} increases, the longer temperature decay requires inclusion of shorter heat pulse (smaller tₚᵤₗₛₑ) and a longer time between pulses (t_{off}) to produce the same pressure pulse magnitude. In addition, the number of pulses required before obtaining the steady state pulse shape increases, as it takes several pulses for the lower temperature in the temperature pulse to reach its steady state limit.

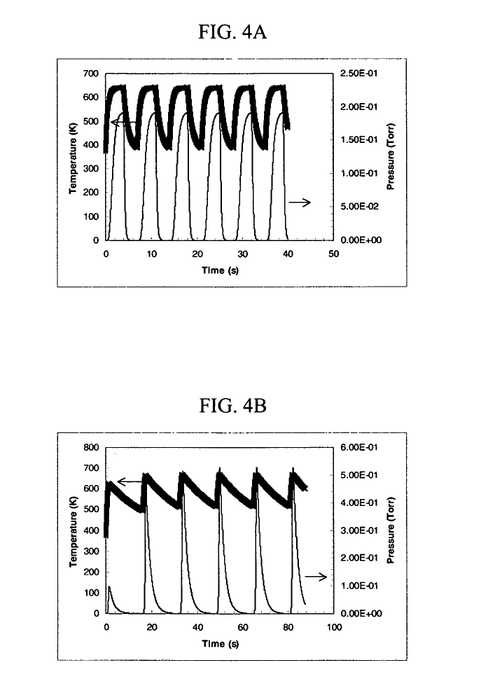

As can be seen from the FIG. 3, t_{off} increases roughly linearly with τ_{c}. The longer the time to cool the surface of the evaporant down, the more time required for the pressure pulse to completely decay. Because the surface Aₛ acts as a sink for condensing vapor, and because the vaporization rate depends exponentially on temperature, the decay time for the vapor pulse is less than τ_{c}, rather than of the order of 5 τ_{c}, as would be expected if the pressure pulse followed the temperature pulse in linear fashion. In the limit of low values for τ_{c}, τ_{V} can become the limiting factor in the pressure decay between pulses. Furthermore, a very low τ_{c} signifies excellent thermal contact between the material in the vaporization region and the region maintained at T_{b}. In such cases the required heat to produce vaporization increases substantially. Calculated pressure and temperature responses are shown in FIGS. 4A and 4B respectively for τ_{c}=1 s and τ_{c}=20 s.

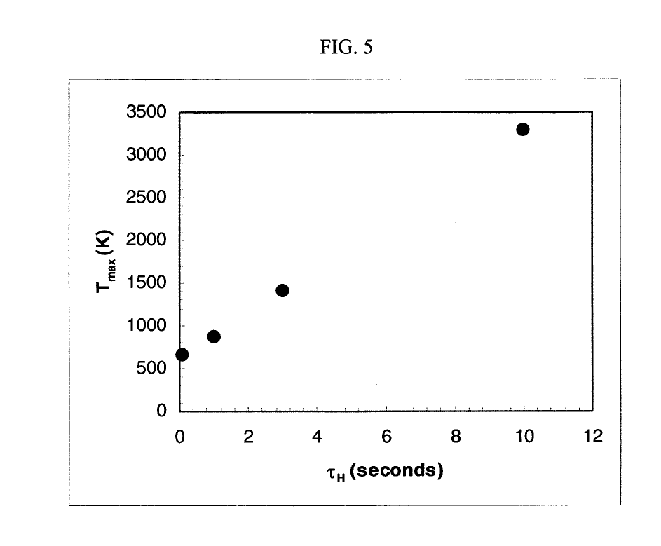

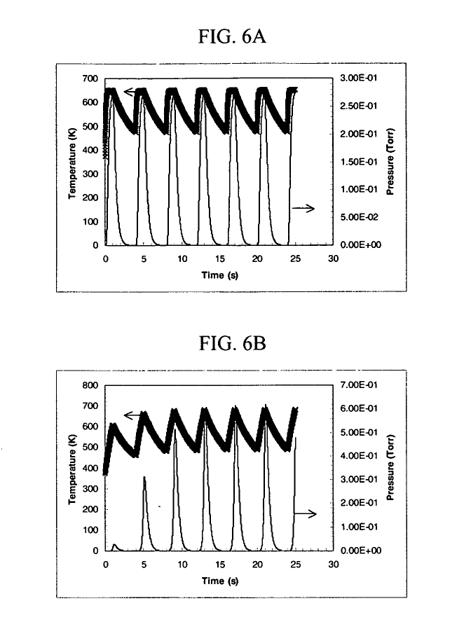

FIG. 5 illustrates the effects of τ_{H}. The data in FIG. 5 were computed with the following settings: T_{b}=373 K, τ_{C}=3 s, tₚᵤₗₛₑ =1 s, t_{off}=3 s, V=0.04 cm×0.04 cm×60 cm=9.6×10⁻⁴ m³, C_{A}=60×0.02 1/s=1.2×10⁻³ m³/s, Aₛ=1 cm×1 cm=1×10⁻⁴ m². (For the values for V and C_{A}, τ_{V}0.8 s). The time step size was 0.005 s. Tₘₐₓ, was adjusted to give similar time-averaged pressure and similar ratios of peak pressure to minimum pressure before the next pulse. As described in the discussion of FIG. 3, the target average pressure was roughly 0.076 Torr, and the same vapor pressure parameters were used for Alq₃. As can be seen from FIG. 5, the larger the value for τ_{H}, the larger the Tₘₐₓ to obtain the same average manifold pressure (which is directly related to the pressure pulse magnitude). Even though the Tₘₐₓ values are increasing with τ_{H}, the actual peak values for Tᵥ are the same (roughly 650 K), and the required time between pulses t_{off} does not change. The significance of the Tₘₐₓ value is that more power input is required in order to make the temperature rise sufficiently rapidly that Tᵥ rises to the required value within the duration of the chosen tₚᵤₗₛₑ. Calculated pressure and temperature responses are shown in FIGS. 6A and 6B respectively for τ_{H}=0.1 s and τ_{H}=10 s.

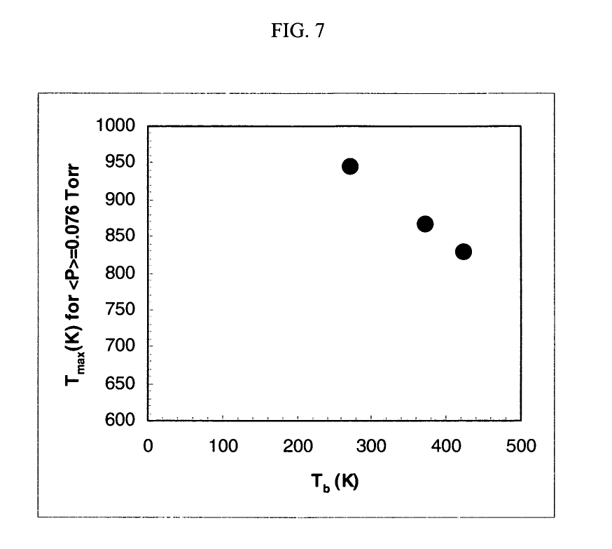

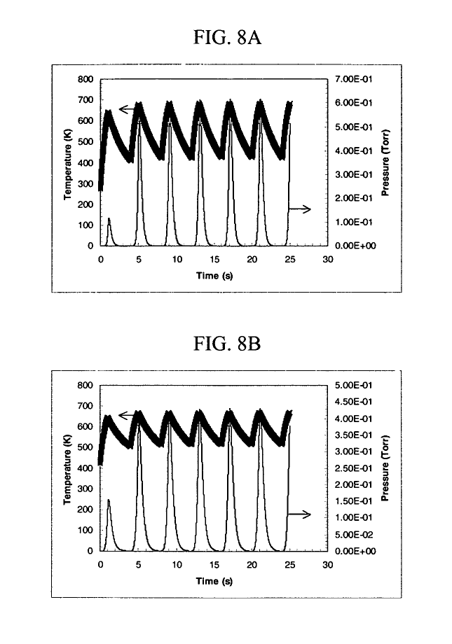

The effect of T_{b} is illustrated in FIG. 7. The data in FIG. 7 were computed with the following settings: τ_{H}=1 s, τ_{c}=3 s, tₚᵤₗₛₑ=1 s, t_{off}=3 s, V=0.04 cm×0.04 cm×60 cm×9.6×10⁻⁴ m³, C_{A}=60×0.02 1/s=1.2×10⁻³ m³/s, Aₛ=1 cm×1 cm=1×10⁻⁴ m². For the values for V and C_{A}, τ_{V}=0.8 s). The time step size was 0.005 s. Tₘₐₓ, was adjusted to give similar time-averaged pressure and similar ratios of peak pressure to minimum pressure before the next pulse. As described in the discussion of FIG. 3, the target average pressure was roughly 0.076 Torr, and the same vapor pressure parameters were used for Alq₃. As can be seen from FIG. 7, as T_{b} increases, Tₘₐₓ decreases in order to obtain the same average manifold pressure (and hence pressure pulse magnitude). As the Tₘₐₓ values change with T_{b}, the actual peak values for Tᵥ also change, but not as dramatically as does Tₘₐₓ. In addition, the pressure pulse shape broadens as T_{b} is increases. If T_{b} is raised too much, the vapor pulse never completely decays, as T_{b} can be high enough to produce significant vaporization and thus contribute to the manifold pressure with no additional heat supplied through the pulsed heating element. When the vapor pressure caused by T_{b} becomes a significant fraction of the peak pressure (i.e. above 0.1%) then the pressure pulse is never “off”. For applications where no significant deposition can occur between pulses, T_{b} must be kept below a certain maximum value. For applications where the rate is modulated above a base value, T_{b} can be set to achieve the base value, and the heat pulse parameters can be selected to achieve the appropriate modulation above the base value. Calculated pressure and temperature responses are shown in FIGS. 8A and 8B respectively for T_{b}=273 K and T_{b}=423 K.

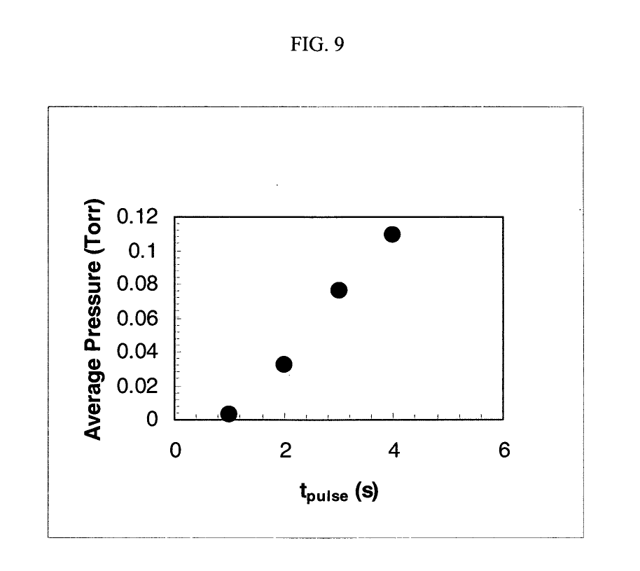

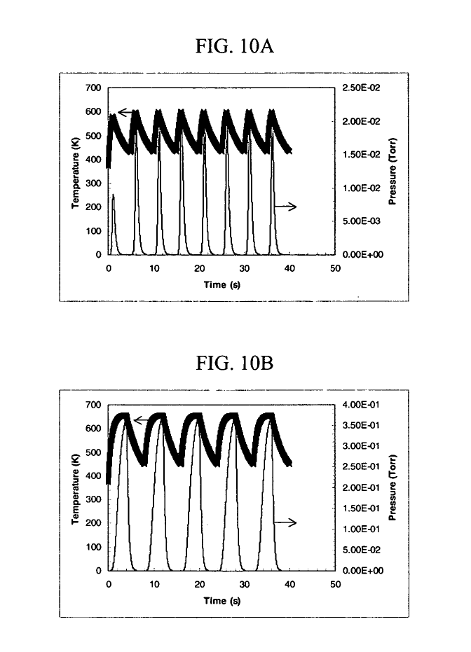

FIG. 9 illustrates the use of tₚᵤₗₛₑ to vary the average manifold pressure (or pressure pulse magnitude). The data in FIGS. 6A and 6B were computed with the following settings: T_{b}=373.16 K, Tₘₐₓ=755 K, t_{off}=4 s, τ_{H}=1 s, C=3 s, t_{off}=3 s, V=0.04 cm×0.04 cm×60 cm=9.6×10⁻⁴ m³, C_{A}=60×0.02 1/s=1.2×10⁻³ m³/5, Aₛ=1 cm×1 cm=1×10⁻⁴ m². For the values for V and C_{A}, τ_{V}=0.8 s). The time step size was 0.005 s. The same vapor pressure parameters were used for Alq₃ as described above. tₚᵤₗₛₑ, was varied to illustrate its effect on the average manifold pressure. Consequently, the pressure pulse width increased with tₚᵤₗₛₑ. Over the range of values used for tₚᵤₗₛₑ, the pressure decay between pulses during t_{off} was not significantly affected by changing tₚᵤₗₛₑ. As can be seen from FIG. 9, the average manifold pressure (and pressure pulse magnitude) and hence the deposition rate (or material deposited per pulse) can be varied substantially by changing tₚᵤₗₛₑ. Thus, FIG. 9 illustrates pulse width modulation of the vapor emitted from the source. Calculated pressure and temperature responses are shown in FIGS. 10A and 10B respectively for tₚᵤₗₛₑ=1 s and tₚᵤₗₛₑ=4 s.

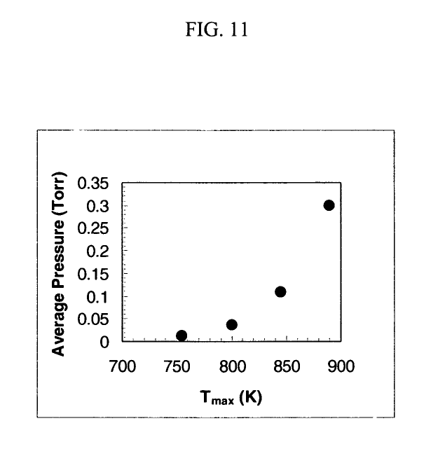

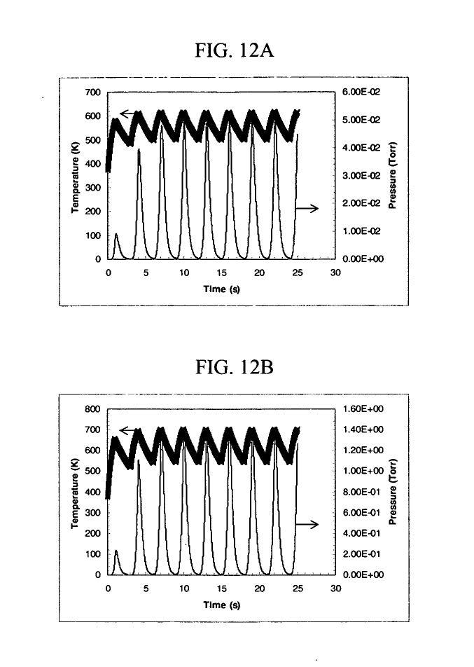

FIG. 11 illustrates the use of Tₘₐₓ to vary the average manifold pressure (or pressure pulse magnitude). The data in FIG. 11 were computed with the following settings: T_{b}=373.16 K, tₚᵤₗₛₑ=1 s, t_{off}=2 s, τ_{H}=1 s, τ_{C}=3 s, V=0.04 cm×0.04 cm×60 cm=9.6×10⁻⁴ m³, C_{A}=60×0.021/s=1.2×10⁻³ m³/s, Aₛ=1 cm×1 cm=1×10⁻⁴ m². (For the values for V and C_{A}, τ_{V}=0.8 s). The time step size was 0.005 s. The same vapor pressure parameters were used for Alq₃ as described above. Tₘₐₓ was varied to illustrate its effect on the average manifold pressure. Consequently, the pressure pulse height increased with tₚᵤₗₛₑ. Over the range of values used for Tₘₐₓ, the pressure decay between pulses during t_{off} was not significantly affected by changing tₚᵤₗₛₑ. As can be seen from FIG. 11, the average manifold pressure (and pressure pulse magnitude) and hence the deposition rate (or material deposited per pulse) can be varied substantially by changing Tₘₐₓ. Thus, FIG. 11 illustrates pulse height (or pulse amplitude) modulation of the vapor emitted from the source. Calculated pressure and temperature responses are shown in FIGS. 12A and 12B respectively for Tₘₐₓ=755 K and tₘₐₓ=890 K.

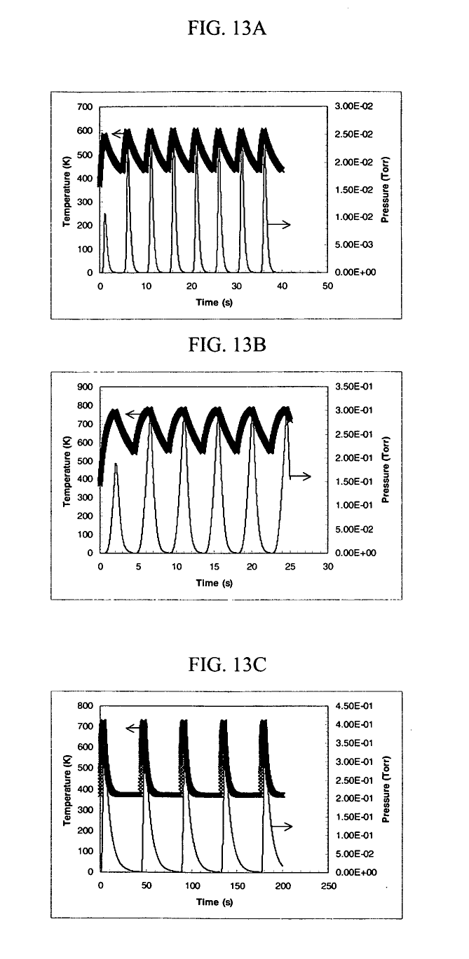

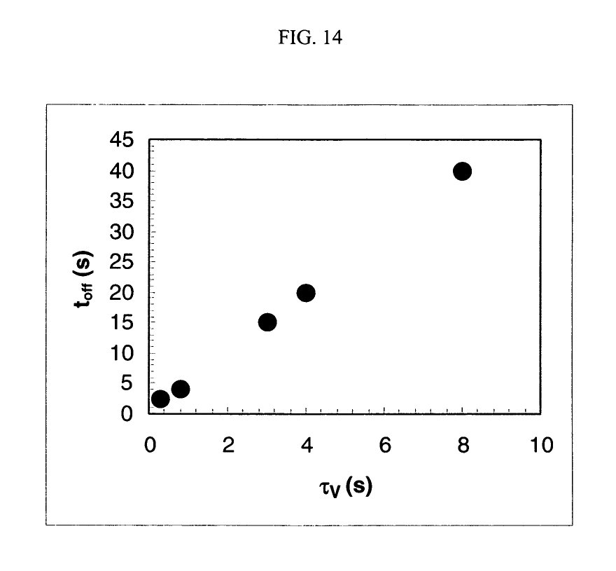

FIGS. 13A-C and 14 illustrates the effect of evaporant surface area and τTᵥ. The calculate pressure and temperature responses in FIG. 13A were computed with the following settings: T_{b}=373.16 K, tₚᵤₗₛₑ=1 s, t_{off}=4 s, τ_{H}=1 s, τ_{C}=3 s, V=0.04 cm×0.04 cm×60 cm=9.6×10⁻⁴ m³, C_{A}=60×0.0002 1/s=1.2×10⁻⁵ m³/s, Aₛ=1 cm×1 cm=1×10⁻⁴ m². (For the values for V and C_{A}, τᵥ=80 s). The time step size was 0.008 s. Despite the high value for τ_{V}, the response of the manifold is quite similar to that shown in FIG. 10A, which shows the response for the same settings except with τ_{V}=0.8 s (C_{A}=.1.2×10⁻³ m³/s). A minor effect of the large τ_{V} is the higher peak pressure value for the pressure pulses. The overall response, however is quite similar. FIGS. 13B and 13C illustrate how the area Aₛ plays a role. The calculated pressure and temperature responses in FIGS. 13B and 13C were computed with the following settings: T_{b}=373.16 K, τ_{H}=1 s, τ_{C}=3 s, V=0.04 cm×0.04 cm×60 cm=9.6×10⁻⁴ m³, and Aₛ=0.1 cm×0.1 cm=1×10⁻⁶ m². C_{A} was adjusted so that τᵥ was 0.3 s in FIGS. 13B and 8 s in FIG. 13C. Tₘₐₓ, t_{off} and tₚᵤₗₛₑ were adjusted to produce similar average pressure values with similar ratios of peak pressure to minimum pressure before the next pulse. The time step was adjusted to obtain a comparable number of heat pulses as t_{off} increased. Additional calculations were performed in similar fashion with C_{A} adjusted so that τᵥ was 0.8, 3, and 4 s. The resultant t_{off} required for sufficient decay of the heat pulses is plotted against Tᵥ in FIG. 14. As can be seen from FIGS. 13B, 13C, and 14, the significantly smaller (i.e. by a factor of 100) value for Aₛ results in sensitivity of the response to the value of τ_{V}. In this regime, the time between pulses must be set to roughly 5τ_{V}, as the aperture conductance is now the limiting factor the decay of the manifold pressure between pulses. Thus, the area of the evaporant in contact with the heating element in the vaporization zone can be increased to improve the response time of the manifold and to significantly reduce the dependence of the manifold response time on τ_{V}.

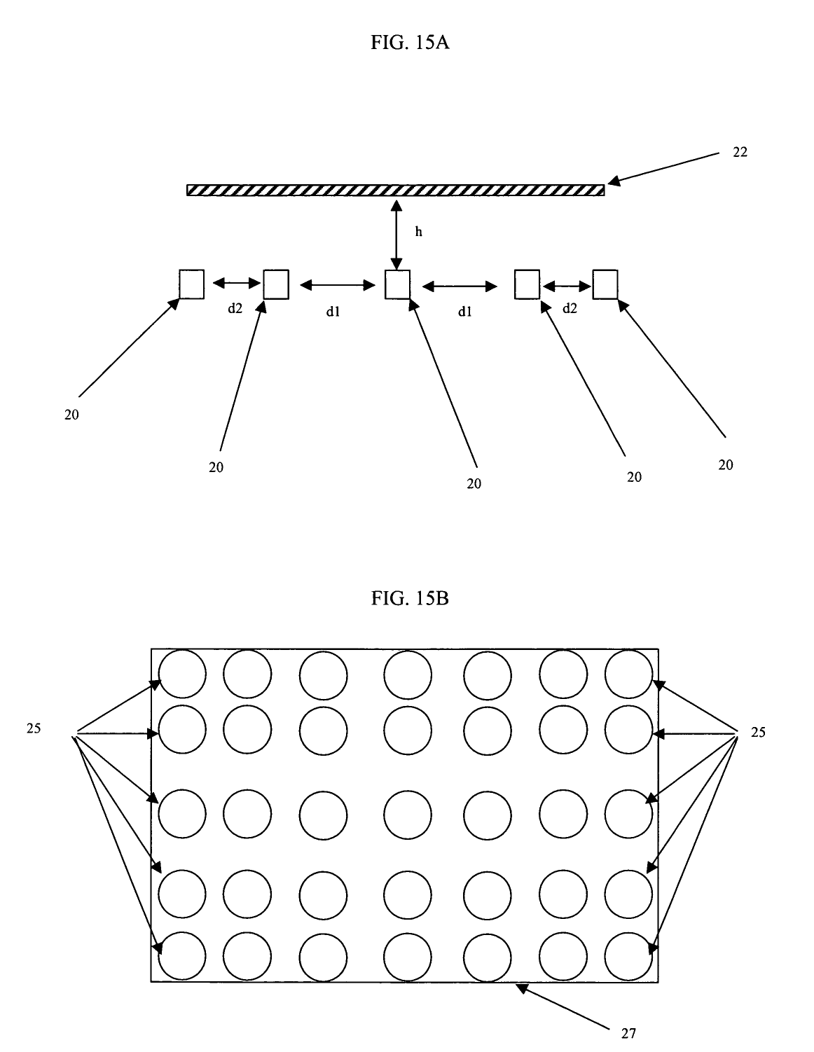

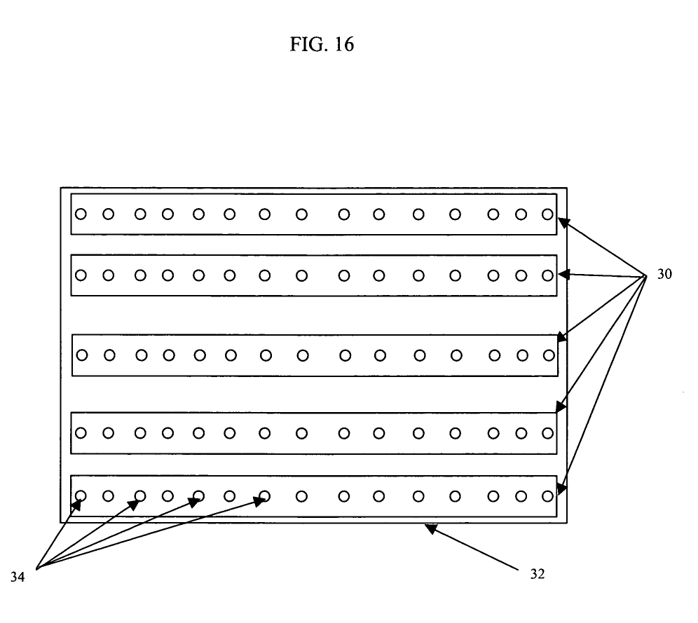

Deposition using heat pulses can be achieved by constructing the manifold to deliver a uniform vapor flux over a specified substrate area or by combining a series of manifolds (FIG. 16), such as a row of elongated manifolds or an array of circular or square manifolds, or some combination thereof. Alternatively, sources without manifolds (FIGS. 15A and 15B) can be arranged to give uniform coatings.

Shown in FIG. 15A is a series of sources 20 are placed along a line beneath a substrate 22. Depending on the degree of uniformity required, the distance h and the number of sources 20 can be chosen appropriately. Furthermore, the spacing d2 between sources near the edges of the substrate can be made smaller than the spacing d1 between sources further from the substrate edges. In addition, the relative deposition rates from the sources 20 can be adjusted to compensate for the finite length effects and consequent drop of thickness near the substrate edges. In particular, sources 20 at the ends can be operated at higher rate than those sources 20 that are further from the substrate edges, and some of those sources further from the substrate edge can be operated at lower rates relative to those sources near the center of the substrate. The relative rates of the various sources can thus be tailored to achieve better uniformity over the length of the substrate 22. The sources 20 can be single material sources, multicomponent (i.e. mixed materials) sources, clusters of sources that deliver different materials simultaneously, or they can be single sources having multiple vaporization zones and thus delivering multiple materials simultaneously. Using pulsed deposition, the control of relative rates of the different materials as well as relative deposition rates from each of the sources along the substrate axis can be achieved by control of the material per pulse as described above, as well as the pulse frequency.

Shown in FIG. 15B is a top view of an array of sources 25 placed beneath a substrate 27. As in FIG. 15A the spacing between sources near the substrate edges can be made smaller than the spacing between sources further from the substrate edge, and the number of sources and the distance between the plane of the sources and the substrate plane can be chosen depending on the degree of coating uniformity required. In addition the relative rates from each source can be adjusted depending on position to further improve the uniformity, as discussed for FIG. 15A, and the sources can be single material sources, multicomponent (i.e. mixed materials) sources, clusters of sources that deliver different materials simultaneously, or they can be single sources having multiple vaporization zones and thus delivering multiple materials simultaneously. Control of relative rates of the different materials as well as relative deposition rates from each of the sources can be achieved by control of the material per pulse as described above, as well as the pulse frequency.

Shown in FIG. 16 is a top view of an array of manifolds 30 placed beneath a substrate 32. Each manifold 30 has an aperture 34 or plurality of apertures 34, whose spacing and size are selected so as to produce uniform flux of material along some portion of the manifold length (width of the substrate). The size of the holes and the dimensions of the manifold are selected in accordance with the conductance criterion described in commonly assigned U.S. patent application Ser. No. 10/352,558 filed Jan. 28, 2003 by Jeremy M. Grace et al., entitled “Method of Designing a Thermal Physical Vapor Deposition System”, the disclosure of which is herein incorporated by reference, so as to produce substantially uniform deposition thickness in the lengthwise direction. The manifolds 30 and array of apertures 34 can be longer or shorter than the substrate width, depending on the required uniformity. The spacing between manifolds 30 and the distance from the substrate to the manifold plane are chosen appropriately for the desired uniformity. The manifolds can be single material sources, multicomponent (i.e. mixed materials) sources, or they can be fed by multiple vaporization zones and thus deliver multiple materials simultaneously. Control of relative rates of the different materials as well as relative deposition rates from each of the manifolds can be achieved by control of the material per pulse as described above, as well as the pulse frequency. For codeposition of materials from separate manifolds, the manifolds 30 can also be tilted relative to the manifold-substrate normal so as to optimize mixing of vaporized material components as they travel between the manifold 30 and substrate 32.

By precise control of the amount of material per pulse, the relative amounts of various components can be controlled. For example a host material that is to be dominant in the composition of the deposited film can be deposited using an intense pulse (high value of Tₘₐₓ) or a long pulse (long time tₚᵤₗₛₑ) and a dopant material that is to be a small fraction of the composition of the deposited film can be deposited using a weak pulse (low value of Tₘₐₓ) or a short pulse (short time tₚᵤₗₛₑ).

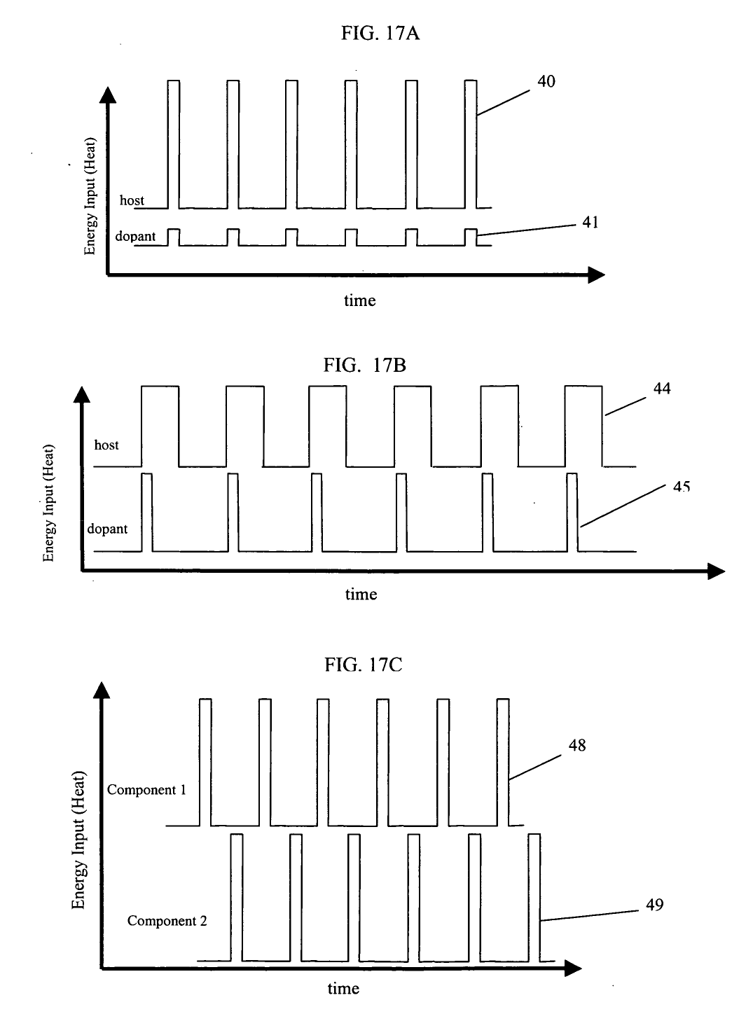

With appropriate construction of the vaporization region and heating element, the shape and size of the heat pulse will determine the amount of material deposited per pulse. Additional control over the relative amounts of components deposited in a film can be gained by delivering different numbers of pulses for each component. Pulse modulation (height or width) and differing pulse count can be used either to tailor the composition within a single layer or to tailor the relative thickness of two distinct layers, depending on the sequencing of the pulses from different vaporization zones. Various heat pulse sequences are illustrated in FIGS. 17A-C. In FIG. 17A, a sequence of heat pulses to deposit a combination of host (i.e. dominant component) and dopant (i.e. component in small concentrations compared to that of the host) by use of different pulse heights is shown. The host pulse 40 is considerably higher than dopant pulse 41. Consequently the layer deposited will have relative amounts of host and dopant in proportion to the area beneath each pulse in the pressure-time plot. In FIG. 17B, a pulse sequence to deposit host and dopant by pulse width variation is shown. The host pulse 44 is considerably longer than the dopant pulse 45. When relative pulse height is used to control relative amounts of materials in a deposited film (as in FIG. 17A), the uniformity of film composition throughout the layer thickness is determined by the degree to which the pulse shapes are similar for the different materials being deposited. When relative pulse length is used to control the relative amounts of materials deposited (as in FIG. 17B), the composition varies over the thickness deposited per pulse, as the shorter pulse delivers its material for a fraction of the deposition time, while the longer pulse continues to deposit after the short pulse is delivered. In either case (i.e. FIGS. 17A and 17B), increasing the vapor time constant τᵥ will improve the mixing of components, provided that τᵥ is much longer than the larger pulse length and is the limiting time constant. In FIG. 17C, a pulse sequence to deposit two distinct layers is shown. A first material is deposited using heat pulses 48 followed by a second material deposited using heat pulses 49. While only two components are shown in FIGS. 17A-17C, it should be apparent that multicomponent or multilayer films can be achieved using the same way illustrated in FIGS. 17A-17C by including heat pulses from additional sources and adjusting their pulse heights or pulse widths or timing relative to other pulses to achieve the desired composition or thickness control within a layer or in multilayer structures.

In the foregoing discussion, it should be appreciated that mechanical pulses can be used in place of or in combination with heat pulses to produce the deposition pulses and control their magnitudes. A mechanical pulse exerting a force of the depositing material against a heating element for a specified time will produce an amount of vaporized material that increases with the duration of the mechanical pulse, in analogous fashion to controlling the amount by heat pulse duration. Furthermore, combining mechanical and heat pulses, the time constant for vaporization to subside can be reduced relative to using heat pulses alone in cases where the cooling time constant τ_{c} is the limiting factor and is determined largely by the cooling response time of the heater.

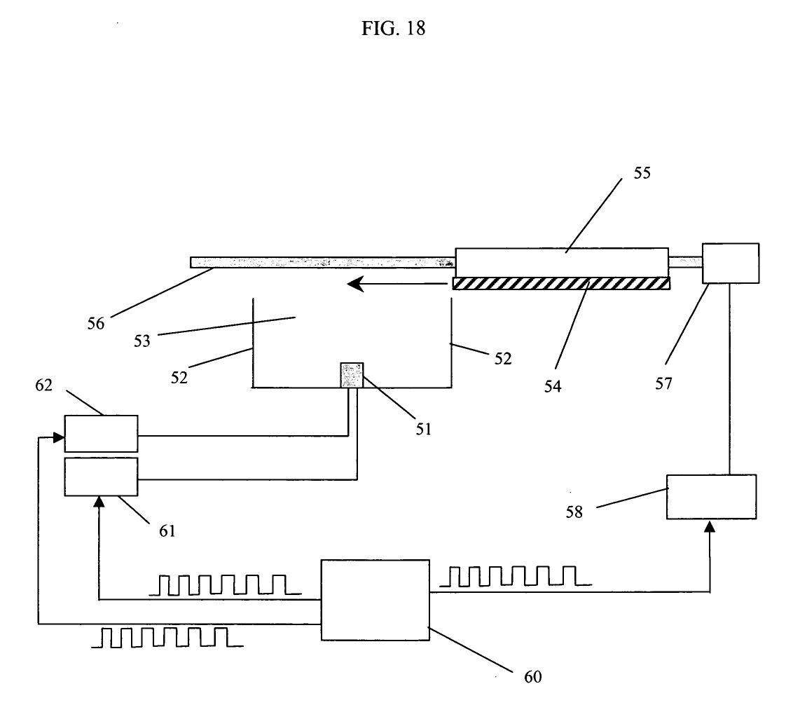

The use of pulse modulation and sequencing to control deposited film thickness and composition limits the need to provide a constant and continuous material feed rate to the vaporization zone. As long as the conditions within the vaporization zone can be reset repeatably between pulses (during t_{off}), the intended controlled amount of material per pulse will be delivered. Furthermore, combining the pulse-wise deposition of material with stepwise motion of a substrate, the need to provide a constant substrate translation speed is limited. FIG. 18 shows control schemes where the generation of heat pulses is synchronized with the material feed and the substrate motion. A flash evaporation source 51 is placed between shields 52 defining a deposition zone 53. A substrate 54 is mounted on a translation stage 55, which is driven along a translation mechanism 56 by a motor 57. A motor control unit 58 is used to control the motion of the stage 55. A master control unit 60 (e.g. computer, microprocessor, etc.) sends control signals to the motor control unit 58, a heat pulse generator 61, and a material feed control unit 62. By appropriate programming and logic, the motion of the substrate 54 is synchronized with the heat pulses and material feed to the flash evaporation source 51. The substrate 54 is moved into position, a heat pulse sequence is applied to the flash evaporation source 51, the evaporant material is advanced, or the feed mechanism is reset or repositioned, and the substrate 54 is then moved into the next position for the next deposition pulse sequence. The process is continued in synchronous stepwise motion until the substrate 54 and stage 55 have passed from one end of the deposition zone 53 to the other.

The flash evaporation source 51 can be as described in commonly assigned U.S. patent application Ser. No. 10/784,585 filed Feb. 23, 2004 by Michael Long et al., entitled “Device and Method for Vaporizing Temperature Sensitive Materials”, the disclosure of which is herein incorporated by reference, or can be some other evaporation source having the capability to deliver pulses of material to be deposited. The substrate translation stage 55 and substrate 54 can include an assembly with masks and other fixtures to produce patterns in the deposited coating. The stage 55, substrate 54, and assembly can be translated with respect the source 51, either by moving the substrate translation stage 55 or by moving the components defining the deposition zone 53 (i.e. source 51, shields 52, and any base plate or fixtures required to translate the deposition zone components together) with respect to the source 51. There can be one or more sources 51 delivering similar or different materials, depending on the required composition and layer structure to be coated. The translation mechanism 56 thus can be position to move the substrate 54 and stage 55 or the source or sources 51 and their shielding 52 and other associated components.

The heat pulse generator 61 can be a closed loop heater control system with multiple outputs and multiple sensor (e.g., thermocouple or other temperature sensing device) inputs. One set of inputs and outputs can be used to maintain the base temperature T_{b} described above. Control schemes can be proportional differential (PD) or proportional-integral-derivative (PID) control, with hardware or software implementation of the closed loop. In addition, feed forward control techniques can be used. For controlling steady state temperatures, heater output can be phase angle fired ac voltage, pulse width modulated dc voltage, asynchronous pulse width modulated ac voltage, or some other way of metering out available power to the heater. For pulsing the heater element (not shown) of source 51, additional outputs and sensors inputs can be used. These heat pulses are used to produce the vapor pulses as described above. Furthermore, additional sensor inputs and heater outputs can be used to maintain the required temperatures on the manifold (not shown) and the aperture surfaces (not shown) of the source 51 using any of a variety of control schemes as described above.

The material feed control unit 62 can be a closed loop control system with multiple sensor inputs and control signal outputs to control one or more material feed mechanisms (not shown). Sensors within the feed mechanism (e.g. to sense force, strain, velocity, displacement, temperature of heating element within source 51, etc.) can be used to control feed rate by use of the control unit 62 employing PD, PID, state variable, feed forward, or other control schemes. Furthermore, the material feed control unit 62 can deliver control pulses to the material feed mechanism in synchronization with heat pulses from the heat pulse generator 61 and substrate motion driven by motor control unit 58. Depending on the feed mechanism, control pulses can not only pause the feeding of material, but also can retract the material or reduce contact with heating elements within the source 51 to accelerate the decay of the vapor pulses delivered by source 51. Alternatively, the control pulses can result in the metering of a desired amount of material in a given cycle.

The motor control unit 58 can be a motion control system with appropriate motion and position sensors and actuators. Synchronization of the substrate 54 motion with heat pulses and material feed is accomplished by communication between the control units 58, 61, 62 and the master control unit 60.

In order to illustrate the concept of depositing uniform layers using synchronous stepwise motion of the substrate and heat pulsing, a model was constructed. This model calculates the coating uniformity along the direction of motion of a substrate moved in stepwise fashion across a deposition zone containing a source that emits a vapor plume of specified shape.

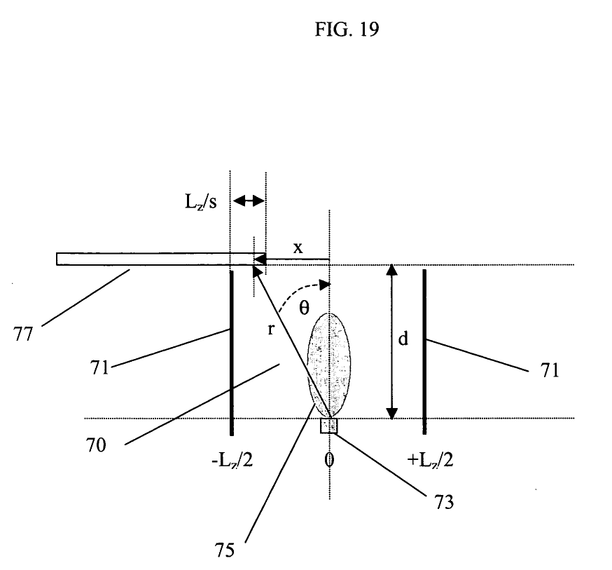

The geometry relevant to the model is shown in FIG. 19. A deposition zone 70 is defined by vertical shields 71 placed at positions +L_{z}/2 and −L_{z}/2 with respect to the center of the deposition source 73. A vapor plume 75 is emitted from the source when heat pulses are applied. A substrate 77 is moved in stepwise fashion with a step size equal to L_{z}/s, where s is the number of steps required to traverse the deposition zone. The effect of the plume shape is expressed as a function of angle θ between the vertical distance d to the substrate 77 and the radial distance from the center of the source 73 to a point x on the substrate 77:
R∝cos^{P}(θ) (5)
where R is the deposition rate and p is a plume shape exponent. Using the relation cos(θ)=d/r, one finds:

$$R ∝ \frac{{cos}^{p + q + 1} ( θ )}{{d}^{q}} \qquad ( 6 )$$

where q=1 for a line source, q=2 for a point source, and the additional 1 in the exponent arises from the dot product of the deposition flux with the substrate normal. Using Eq. 6, the relative amount of material deposited along a substrate segment moving in s steps is found by integrating the relative rate R along the step size (expressing θ as a function of x and integrating over x values along the substrate step), moving the substrate by a step L_{z}/s in the x direction, integrating R again, and accumulating all the contributions along the step size for all s steps. From the resultant distribution of material along the step length, the nonuniformity along the substrate (defined here as the range of the thickness values divided by the average of the values) is calculated to be 2(max−min)/(max+min), where min and max are respectively the minimum and maximum accumulated thicknesses along the substrate segment. Input parameters to the model are L_{z}, d, p, q, and s.

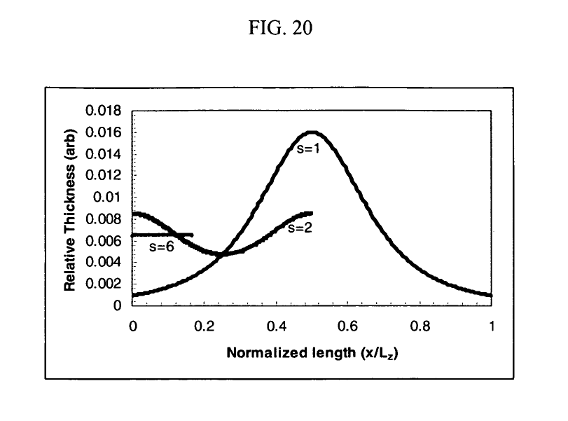

Shown in FIG. 20 are three deposition profiles along the substrate segment Lz/s. These profiles were calculated using d=10 cm, Lz=40 cm, and p=1.5. The highly peaked profile is for the case s=1 and reveals the plume shape used in obtaining the modeled profile. The u-shaped profile is for the case s=2, where the edges of the substrate are exposed to the maximum deposition rate (x=0) as the step size is half the length of the deposition zone. The flat profile is for the case s=6 and is considerably uniform (nonuniformity =0.003, or 0.3%).

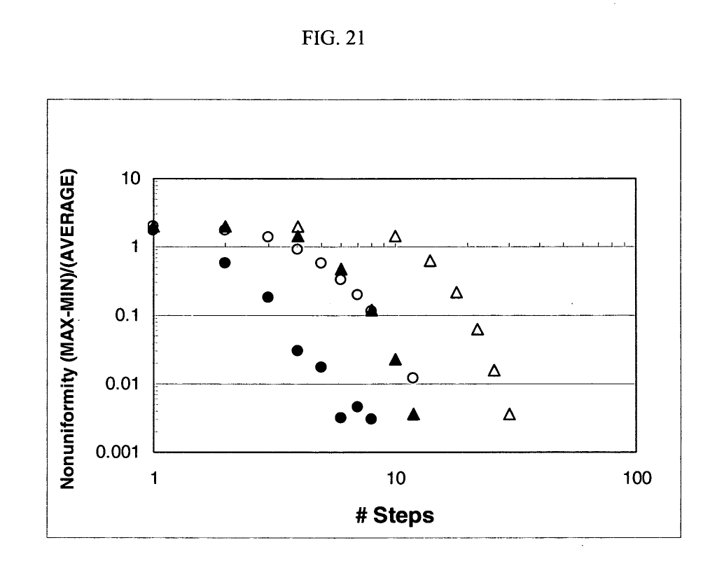

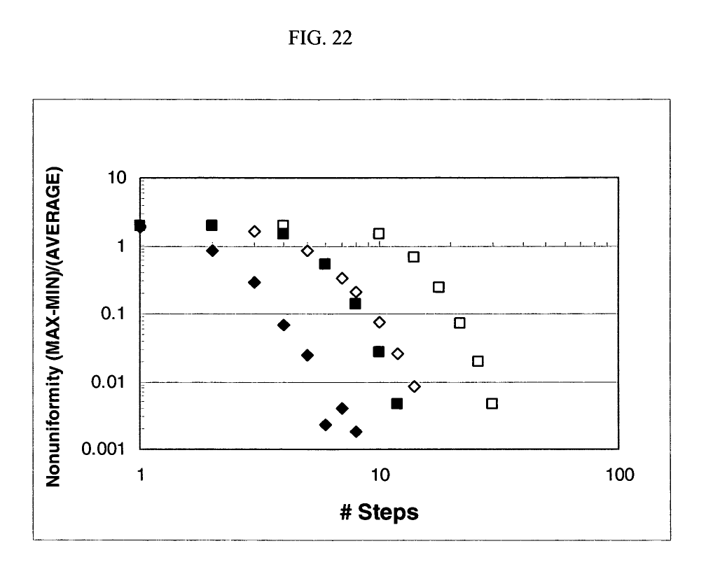

FIGS. 21 and 22 show the results for calculated nonuniformity as a function of number of steps s for two plume shapes and two vertical distances d, respectively for a line source (q=1) and a point source (q=2). In FIG. 21, calculations are for p=1.5 and d=10 (●), p=20 and d=10 (▴), p=1.5 and d=4 (◯), and p=20 and d=4 (Δ). In FIG. 22, calculations are for p=1.5 and d=10 (♦), p=20 and d=10 (▪), p=1.5 and d=4 (⋄), and p=20 and d=4 (□). As can be seen from FIGS. 21 and 22, for minimum number of steps and lowest nonuniformity, a broader plume (lower value of p) is preferred. FIGS. 21 and 22 also show that similar results are obtained for point source and linear sources under the conditions modeled.

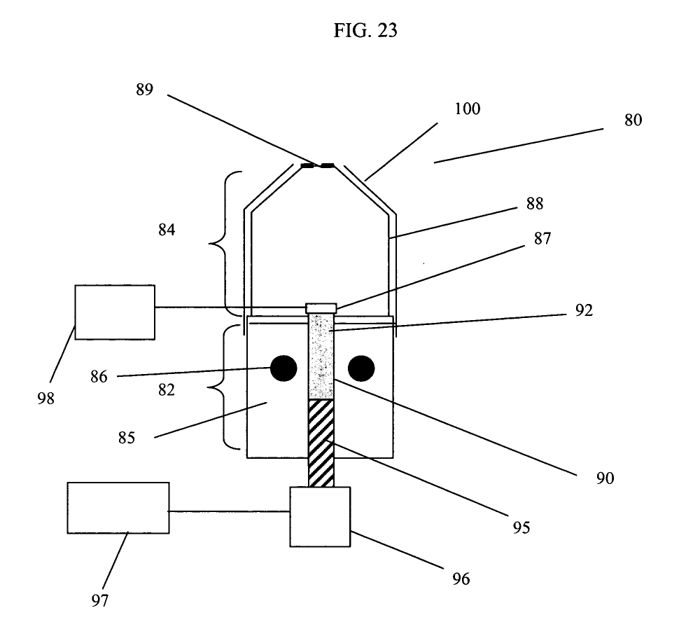

Turning now to FIG. 23, there is shown a cross-sectional view of a flash evaporation source suitable for pulsed evaporation and synchronous pulsed evaporation and substrate motion of the present invention. Vaporization apparatus 80 vaporizes materials onto a substrate surface to form a film, and includes a first heating region 82 and a second heating region 84 spaced from first heating region 82. First heating region 82 includes a first heating arrangement represented by base block 85, which can be a heating base block or a cooling base block, or both, and which can include control passage 86. Second heating region 84 includes the region bounded by manifold 88 and heating element 87, which can be part of manifold 88. The heating element 87 can be permeable or can be otherwise shaped to permit vaporized material to escape in the direction of the manifold 88. A feature of the heating element 87 is its response time, which not only depends on its construction but also depends on its thermal contact to the base block 85 through fixturing and the material 92. Shorter response time enables higher frequency pulsing of the heating element 87. Manifold 88 also includes one or more apertures 89. The region of the manifold 88 having the apertures 89 can be separately heated to ensure that the exit surfaces of the manifold (i.e. inner walls of apertures 89 and surfaces of manifold 88 near the apertures 89) are sufficiently hot so as to avoid condensation of vapor and consequent obstruction of the exit volume. Chamber 90 can receive a quantity of material 92 (i.e. evaporant, sublimate, material to be deposited). A way of metering material 92 includes chamber 90 for receiving the material 92, piston 95 for raising material 92 in chamber 90, as well as heating element 87.

A drive unit 96 advances the piston. For extended runs, the piston 95 and drive unit 96 can be replaced by a mechanism for continuous feed of powder, solid formed from compressed or melt cast material, or liquid. A drive control unit 97 provides control signals to the drive unit 96 and can be used to program the motion of the piston 95 or to control the metering of material by an alternative material feed mechanism. A heating element control unit 98 provides current or voltage waveforms (i.e. pulses, alternating-current, or direct-current voltages or currents) to the heating element 87. Additional heater control units (not shown) maintain the manifold 88 and base block 85 at their respective constant temperatures. Vaporization apparatus 80 can include one or more radiation shields 100.

Material 92 is preferably either a compacted or precondensed solid. However, material in powder form is also acceptable. Material 92 can comprise a single component, or can comprise two or more components, each one having a different vaporization temperature. Material 92 is in close thermal contact with the first heating arrangement that is base block 85. Control passages 86 through this block permit the flow of a temperature control fluid, that is, a fluid adapted to either absorb heat from or deliver heat to the first heating region 82. The fluid can be a gas or a liquid or a mixed phase. Vaporization apparatus 80 pumps fluid through control passages 86. Applicable pumping arrangements, not shown, are well known to those skilled in the art. Material 92 is heated in first heating region 82 until it is at the desired base temperature T_{b} as described above. First heating region 82 is maintained at a constant temperature as material 92 is consumed.

Material 92 is metered at a controlled rate from first heating region 82 to second heating region 84. Second heating region 84 is heated to a temperature above the desired vaporization temperature Tᵥ discussed above. The temperature of first heating region 82 is maintained at T_{b}, while the temperature of second heating region 84 is at or above the desired rate-dependent vaporization temperature Tᵥ. In this embodiment, second heating region 84 includes the region bounded by manifold 88. Material 92 is pushed against heating element 87 by piston 95. The heating element 87 or the piston 95 or alternative feed mechanism or both can be pulsed by their respective control units 97 and 98.

Where a manifold 88 is used, a pressure develops as described above and vapor exits the manifold 88 through the series of apertures 89. The conductance along the length of the manifold is designed to be roughly two orders of magnitude larger than the sum of the aperture conductances as described in commonly assigned U.S. patent application Ser. No. 10/352,558 filed Jan. 28, 2003 by Jeremy M. Grace et al., entitled “Method of Designing a Thermal Physical Vapor Deposition System”, the disclosure of which is herein incorporated by reference. This conductance ratio promotes effective pressure uniformity within manifold 88 and thereby reduces flow nonuniformities through apertures 89 distributed along the length of the source despite potential local nonuniformities in pressure.

One or more radiation shields 100 are located adjacent the heated manifold 88 for the purpose of reducing the heat radiated to the facing target substrate. These heat shields are thermally connected to base block 85 for the purpose of drawing heat away from the shields. The upper portion of shields 100 is designed to lie below the plane of the apertures for the purpose of reducing vapor condensation on their relatively cool surfaces.

Because only a small portion of material 92, the portion resident in second heating region 84 and nearest the heating element 87, is heated to Tᵥ, while the bulk of the material is kept well below Tᵥ, it is possible to interrupt the vaporization by way of interrupting heating in the second heating region 84, e.g. turning off the heat supply to the heating element 87 or stopping the movement of piston 95 (or alternative material feed mechanism), actively withdrawing material from the second heating region 84 or heating element 87, or includes turning off the heat supply and mechanical manipulation of the material.

Because the heating element 87 can be a fine mesh screen that prevents powder or compacted material from passing freely through it, vaporization apparatus 80 can be used in any orientation. For example, vaporization apparatus 80 can be oriented 180° from what is shown in FIG. 18 so as to coat a substrate placed below it. This is an advantage not found in the heating boats of the prior art.

Although one preferred embodiment has been the use of vaporization apparatus 80 with a powder or compressed material that sublimes when heated, in some embodiments material 92 can be a material that liquefies before vaporization, and can be a liquid at the temperature of first heating region 82. In such a case, heating element 87 can absorb and retain liquefied material 92 in a controllable manner via capillary action, thus permitting control of vaporization rate.

Because the pressure in a pulsed flash evaporation source (such a depicted in FIG. 23, or some other source wherein material is vaporized in pulses and introduced into a deposition zone beneath a substrate) is not constant, the conductance to vapor flow will vary with time to the extent that a pressure dependent conductance exists (e.g. in transition or molecular flow). When a manifold is used, it can be desirable to introduce an inert gas into the manifold to keep the pressure inside the manifold sufficiently high to maintain the low conductance ratio (conductance of vapor flow exiting the manifold to conductance of vapor flow within the manifold). Argon and nitrogen can be used for this purpose, as well as any gas known not to react unfavorably with the material to be deposited or any gas known to react favorably with the material to be deposited (such as commonly done in reactive evaporation or reactive sputtering other reactive deposition technologies).

Other embodiments of flash evaporation sources suitable for pulse-mode operation include sources wherein material to be deposited is introduced in aerosol form, nanoparticulate form, entrained in a stream of carrier gas, wire form, rod form, or liquid form.

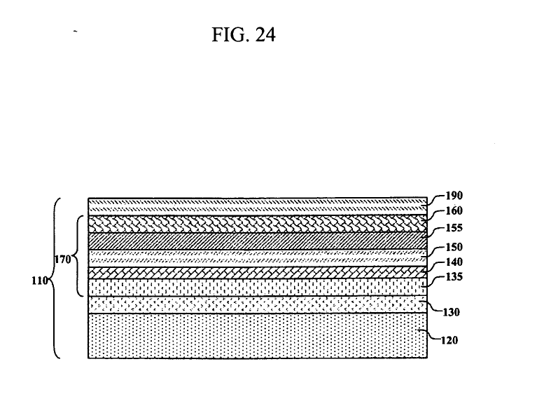

Turning now to FIG. 24, there is shown a cross-sectional view of a pixel of a light-emitting OLED device 110 that can be prepared in part according to the present invention. The OLED device 110 includes at a minimum a substrate 120, a cathode 190, an anode 130 spaced from cathode 190, and a light-emitting layer 150. The OLED device can also include a hole-injecting layer 135, a hole-transporting layer 140, an electron-transporting layer 155, and an electron-injecting layer 160. Hole-injecting layer 135, hole-transporting layer 140, light-emitting layer 150, electron-transporting layer 155, and electron-injecting layer 160 comprise a series of organic layers 170 disposed between anode 130 and cathode 190. Organic layers 170 are the layers most desirably deposited by the device and method of this invention. These components will be described in more detail.

Substrate 120 can be an organic solid, an inorganic solid, or include organic and inorganic solids. Substrate 120 can be rigid or flexible and can be processed as separate individual pieces, such as sheets or wafers, or as a continuous roll. Typical substrate materials include glass, plastic, metal, ceramic, semiconductor, metal oxide, semiconductor oxide, semiconductor nitride, or combinations thereof. Substrate 120 can be a homogeneous mixture of materials, a composite of materials, or multiple layers of materials. Substrate 120 can be an OLED substrate, that is a substrate commonly used for preparing OLED devices, e.g. active-matrix low-temperature polysilicon or amorphous-silicon TFT substrate. The substrate 120 can either be light transmissive or opaque, depending on the intended direction of light emission. The light transmissive property is desirable for viewing the EL emission through the substrate. Transparent glass or plastic are commonly employed in such cases. For applications where the EL emission is viewed through the top electrode, the transmissive characteristic of the bottom support is immaterial, and therefore can be light transmissive, light absorbing or light reflective. Substrates for use in this case include, but are not limited to, glass, plastic, semiconductor materials, ceramics, and circuit board materials, or any others commonly used in the formation of OLED devices, which can be either passive-matrix devices or active-matrix devices.

An electrode is formed over substrate 120 and is most commonly configured as an anode 130. When EL emission is viewed through the substrate 120, anode 130 should be transparent or substantially transparent to the emission of interest. Common transparent anode materials useful in this invention are indium-tin oxide and tin oxide, but other metal oxides can work including, but not limited to, aluminum- or indium-doped zinc oxide, magnesium-indium oxide, and nickel-tungsten oxide. In addition to these oxides, metal nitrides such as gallium nitride, metal selenides such as zinc selenide, and metal sulfides such as zinc sulfide, can be used as an anode material. For applications where EL emission is viewed through the top electrode, the transmissive characteristics of the anode material are immaterial and any conductive material can be used, transparent, opaque or reflective. Example conductors for this application include, but are not limited to, gold, iridium, molybdenum, palladium, and platinum. The preferred anode materials, transmissive or otherwise, have a work function of 4.1 eV or greater. Desired anode materials can be deposited by any suitable way such as evaporation, sputtering, chemical vapor deposition, or electrochemical processes. Anode materials can be patterned using well known photolithographic processes.

While not always necessary, it is often useful that a hole-injecting layer 135 be formed over anode 130 in an organic light-emitting display. The hole-injecting material can serve to improve the film formation property of subsequent organic layers and to facilitate injection of holes into the hole-transporting layer. Suitable materials for use in hole-injecting layer 135 include, but are not limited to, porphyrinic compounds as described in U.S. Pat. No. 4,720,432, plasma-deposited fluorocarbon polymers as described in U.S. Pat. No. 6,208,075, and inorganic oxides including vanadium oxide (VOx), molybdenum oxide (MoOx), nickel oxide (NiOx), etc. Alternative hole-injecting materials reportedly useful in organic EL devices are described in EP 0 891 121 A1 and EP 1 029 909 A1.

While not always necessary, it is often useful that a hole-transporting layer 140 be formed and disposed over anode 130. Desired hole-transporting materials can be deposited by any suitable way such as evaporation, sputtering, chemical vapor deposition, electrochemical processes, thermal transfer, or laser thermal transfer from a donor material, and can be deposited by the device and method described herein. Hole-transporting materials useful in hole-transporting layer 140 are well known to include compounds such as an aromatic tertiary amine, where the latter is understood to be a compound containing at least one trivalent nitrogen atom that is bonded only to carbon atoms, at least one of which is a member of an aromatic ring. In one form the aromatic tertiary amine can be an arylamine, such as a monoarylamine, diarylamine, triarylamine, or a polymeric arylamine. Exemplary monomeric triarylamines are illustrated by Klupfel et al. in U.S. Pat. No. 3,180,730. Other suitable triarylamines substituted with one or more vinyl radicals and/or comprising at least one active hydrogen-containing group are disclosed by Brantley et al. in U.S. Pat. Nos. 3,567,450 and 3,658,520.

A more preferred class of aromatic tertiary amines are those which include at least two aromatic tertiary amine moieties as described in U.S. Pat. Nos. 4,720,432 and 5,061,569. Such compounds include those represented by structural Formula A 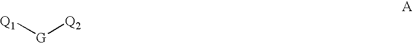
wherein:

Q₁ and Q₂ are independently selected aromatic tertiary amine moieties; and
G is a linking group such as an arylene, cycloalkylene, or alkylene group of a carbon to carbon bond.

In one embodiment, at least one of Q1 or Q2 contains a polycyclic fused ring structure, e.g., a naphthalene. When G is an aryl group, it is conveniently a phenylene, biphenylene, or naphthalene moiety.

A useful class of triarylamines satisfying structural Formula A and containing two triarylamine moieties is represented by structural Formula B 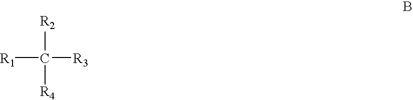
where:

R₁ and R₂ each independently represent a hydrogen atom, an aryl group, or an alkyl group or R₁ and R₂ together represent the atoms completing a cycloalkyl group; and
R₃ and R₄ each independently represent an aryl group, which is in turn substituted with a diaryl substituted amino group, as indicated by structural Formula C 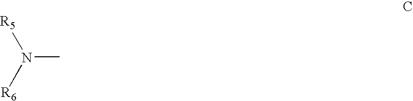
   wherein R₅ and R₆ are independently selected aryl groups. In one embodiment, at least one of R₅ or R₆ contains a polycyclic fused ring structure, e.g., a naphthalene.

Another class of aromatic tertiary amines are the tetraaryldiamines. Desirable tetraaryldiamines include two diarylamino groups, such as indicated by Formula C, linked through an arylene group. Useful tetraaryldiamines include those represented by Formula D 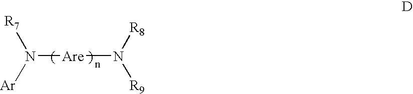
wherein:
each Are is an independently selected arylene group, such as a phenylene or anthracene moiety;
n is an integer of from 1 to 4; and
Ar, R₇, R₈, and R₉ are independently selected aryl groups.

In a typical embodiment, at least one of Ar, R₇, R₈, and R₉ is a polycyclic fused ring structure, e.g., a naphthalene.

The various alkyl, alkylene, aryl, and arylene moieties of the foregoing structural Formulae A, B, C, D, can each in turn be substituted. Typical substituents include alkyl groups, alkoxy groups, aryl groups, aryloxy groups, and halogens such as fluoride, chloride, and bromide. The various alkyl and alkylene moieties typically contain from 1 to about 6 carbon atoms. The cycloalkyl moieties can contain from 3 to about 10 carbon atoms, but typically contain five, six, or seven carbon atoms—e.g., cyclopentyl, cyclohexyl, and cycloheptyl ring structures. The aryl and arylene moieties are usually phenyl and phenylene moieties.

The hole-transporting layer in an OLED device can be formed of a single or a mixture of aromatic tertiary amine compounds. Specifically, one can employ a triarylamine, such as a triarylamine satisfying the Formula B, in combination with a tetraaryldiamine, such as indicated by Formula D. When a triarylamine is employed in combination with a tetraaryldiamine, the latter is positioned as a layer interposed between the triarylamine and the electron-injecting and transporting layer. The device and method described herein can be used to deposit single- or multi-component layers, and can be used to sequentially deposit multiple layers.

Another class of useful hole-transporting materials includes polycyclic aromatic compounds as described in EP 1 009 041. In addition, polymeric hole-transporting materials can be used such as poly(N-vinylcarbazole) (PVK), polythiophenes, polypyrrole, polyaniline, and copolymers such as poly(3,4-ethylenedioxythiophene)/poly(4-styrenesulfonate) also called PEDOT/PSS.

Light-emitting layer 150 produces light in response to hole-electron recombination. Light-emitting layer 150 is commonly disposed over hole-transporting layer 140. Desired organic light-emitting materials can be deposited by any suitable way such as evaporation, sputtering, chemical vapor deposition, electrochemical processes, or radiation thermal transfer from a donor material, and can be deposited by the device and method described herein. Useful organic light-emitting materials are well known. As more fully described in U.S. Pat. Nos. 4,769,292 and 5,935,721, the light-emitting layers of the organic EL element comprise a luminescent or fluorescent material where electroluminescence is produced as a result of electron-hole pair recombination in this region. The light-emitting layers can be comprised of a single material, but more commonly include a host material doped with a guest compound or dopant where light emission comes primarily from the dopant. The dopant is selected to produce color light having a particular spectrum. The host materials in the light-emitting layers can be an electron-transporting material, as defined below, a hole-transporting material, as defined above, or another material that supports hole-electron recombination. The dopant is usually chosen from highly fluorescent dyes, but phosphorescent compounds, e.g., transition metal complexes as described in WO 98/55561, WO 00/18851, WO 00/57676, and WO 00/70655 are also useful. Dopants are typically coated as 0.01 to 10% by weight into the host material. The device and method described herein can be used to coat multi-component guest/host layers without the need for multiple vaporization sources.

Host and emitting molecules known to be of use include, but are not limited to, those disclosed in U.S. Pat. Nos. 4,768,292; 5,141,671; 5,150,006; 5,151,629; 5,294,870; 5,405,709; 5,484,922; 5,593,788; 5,645,948; 5,683,823; 5,755,999; 5,928,802; 5,935,720; 5,935,721; and 6,020,078.

Metal complexes of 8-hydroxyquinoline and similar derivatives (Formula E) constitute one class of useful host materials capable of supporting electroluminescence, and are particularly suitable for light emission of wavelengths longer than 500 nm, e.g., green, yellow, orange, and red. 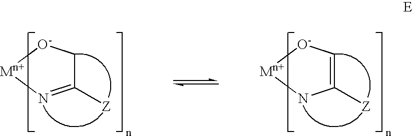
wherein:
M represents a metal;
n is an integer of from 1 to 3; and
Z independently in each occurrence represents the atoms completing a nucleus having at least two fused aromatic rings.

From the foregoing it is apparent that the metal can be a monovalent, divalent, or trivalent metal. The metal can, for example, be an alkali metal, such as lithium, sodium, or potassium; an alkaline earth metal, such as magnesium or calcium; or an earth metal, such as boron or aluminum. Generally any monovalent, divalent, or trivalent metal known to be a useful chelating metal can be employed.

Z completes a heterocyclic nucleus containing at least two fused aromatic rings, at least one of which is an azole or azine ring. Additional rings, including both aliphatic and aromatic rings, can be fused with the two required rings, if required. To avoid adding molecular bulk without improving on function the number of ring atoms is usually maintained at 18 or less.

The host material in light-emitting layer 150 can be an anthracene derivative having hydrocarbon or substituted hydrocarbon substituents at the 9 and 10 positions. For example, derivatives of 9,10-di-(2-naphthyl)anthracene constitute one class of useful host materials capable of supporting electroluminescence, and are particularly suitable for light emission of wavelengths longer than 400 nm, e.g., blue, green, yellow, orange or red.

Benzazole derivatives constitute another class of useful host materials capable of supporting electroluminescence, and are particularly suitable for light emission of wavelengths longer than 400 nm, e.g., blue, green, yellow, orange or red. An example of a useful benzazole is 2, 2′, 2″-(1,3,5-phenylene)-tris[1-phenyl-1H-benzimidazole].

Desirable fluorescent dopants include perylene or derivatives of perylene, derivatives of anthracene, tetracene, xanthene, rubrene, coumarin, rhodamine, quinacridone, dicyanomethylenepyran compounds, thiopyran compounds, polymethine compounds, pyrilium and thiapyrilium compounds, derivatives of distryrylbenzene or distyrylbiphenyl, bis(azinyl)methane boron complex compounds, and carbostyryl compounds.

Other organic emissive materials can be polymeric substances, e.g. polyphenylenevinylene derivatives, dialkoxy-polyphenylenevinylenes, poly-para-phenylene derivatives, and polyfluorene derivatives, as taught by Wolk et al. in commonly assigned U.S. Pat. No. 6,194,119 B1 and references cited therein.

While not always necessary, it is often useful that OLED device 110 includes an electron-transporting layer 155 disposed over light-emitting layer 150. Desired electron-transporting materials can be deposited by any suitable way such as evaporation, sputtering, chemical vapor deposition, electrochemical processes, thermal transfer, or laser thermal transfer from a donor material, and can be deposited by the device and method described herein. Preferred electron-transporting materials for use in electron-transporting layer 155 are metal chelated oxinoid compounds, including chelates of oxine itself (also commonly referred to as 8-quinolinol or 8-hydroxyquinoline). Such compounds help to inject and transport electrons and exhibit both high levels of performance and are readily fabricated in the form of thin films. Exemplary of contemplated oxinoid compounds are those satisfying structural Formula E, previously described.

Other electron-transporting materials include various butadiene derivatives as disclosed in U.S. Pat. No. 4,356,429 and various heterocyclic optical brighteners as described in U.S. Pat. No. 4,539,507. Benzazoles satisfying structural Formula G are also useful electron-transporting materials.

Other electron-transporting materials can be polymeric substances, e.g. polyphenylenevinylene derivatives, poly-para-phenylene derivatives, polyfluorene derivatives, polythiophenes, polyacetylenes, and other conductive polymeric organic materials such as those listed in Handbook of Conductive Molecules and Polymers, Vols. 1-4, H. S. Nalwa, ed., John Wiley and Sons, Chichester (1997).

An electron-injecting layer 160 can also be present between the cathode and the electron-transporting layer. Examples of electron-injecting materials include alkaline or alkaline earth metals, alkali halide salts, such as LiF mentioned above, or alkaline or alkaline earth metal doped organic layers.

Cathode 190 is formed over the electron-transporting layer 155 or over light-emitting layer 150 if an electron-transporting layer is not used. When light emission is through the anode 130, the cathode material can be comprised of nearly any conductive material. Desirable materials have effective film-forming properties to ensure effective contact with the underlying organic layer, promote electron injection at low voltage, and have effective stability. Useful cathode materials often contain a low work function metal (<3.0 eV) or metal alloy. One preferred cathode material is comprised of a Mg:Ag alloy wherein the percentage of silver is in the range of 1 to 20%, as described in U.S. Pat. No. 4,885,221. Another suitable class of cathode materials includes bilayers comprised of a thin layer of a low work function metal or metal salt capped with a thicker layer of conductive metal. One such cathode is comprised of a thin layer of LiF followed by a thicker layer of A1 as described in U.S. Pat. No. 5,677,572. Other useful cathode materials include, but are not limited to, those disclosed in U.S. Pat. Nos. 5,059,861; 5,059,862; and 6,140,763.

When light emission is viewed through cathode 190, it must be transparent or nearly transparent. For such applications, metals must be thin or one must use transparent conductive oxides, or include these materials. Optically transparent cathodes have been described in more detail in U.S. Pat. No. 5,776,623. Cathode materials can be deposited by evaporation, sputtering, or chemical vapor deposition. When needed, patterning can be achieved through many well known methods including, but not limited to, through-mask deposition, integral shadow masking as described in U.S. Pat. No. 5,276,380 and EP 0 732 868, laser ablation, and selective chemical vapor deposition.

Cathode materials can be deposited by evaporation, sputtering, or chemical vapor deposition. When needed, patterning can be achieved through many well known methods including, but not limited to, through-mask deposition, integral shadow masking as described in U.S. Pat. No. 5,276,380 and EP 0 732 868, laser ablation, and selective chemical vapor deposition.

In addition to deposition of organic materials (in particular for OLED devices), the invention can also be used to deposit organic or inorganic materials for other applications in similar fashion. For high-temperature materials (i.e. materials requiring temperatures in excess of 800 K to obtain useful vapor pressures), it can be desirable to omit the manifold and to have an array of heat pulse vaporization sources (linear or two-dimensional) to achieve the desired coating uniformity over a large substrate without subjecting said substrate to excessive heating from the manifold. Alternatively, the manifold can be housed inside a heat shield or a plurality of heat shields, the outermost of which can be cooled so as to prevent excessive radiant heating of the substrate during deposition.

The invention has been described in detail with particular reference to certain preferred embodiments thereof, but it will be understood that variations and modifications can be effected within the spirit and scope of the invention.

### PARTS LIST

1 deposition source
2 manifold
3 exit surface
4 aperture
5 evaporant
6 vaporization region
7 heating element
8 region of lower temperature
9 heat pulse
20 sources
22 substrate
25 sources
27 substrate
30 manifold
32 substrate
34 aperture
40 host pulse
41 dopant pulse
44 host pulse
45 dopant pulse
48 heat pulses
49 heat pulses
51 flash evaporation source
52 shields
53 deposition zone
54 substrate
55 translation stage
56 translation mechanism
57 motor
58 motor control unit
60 master control unit
61 heat pulse generator
62 material feed control unit
70 deposition zone
71 vertical shields
73 deposition source
75 vapor plume
77 substrate
80 vaporization apparatus
82 first heating region
84 second heating region
85 base block
86 control passage
87 heating element
88 manifold
89 aperture(s)
90 chamber
92 material
95 piston
96 drive unit
97 drive control unit
98 heating element control unit
100 radiation shields
110 OLED device
120 substrate
130 anode
135 hole-injecting layer
140 hole-transporting layer
150 light-emitting layer
155 electron-transporting layer
160 electron-injecting layer
170 organic layers
190 cathode

1. A method for vaporizing material onto a substrate surface to form a film, comprising:
a) providing a quantity of material into a vaporization apparatus;
b) heating the material in the vaporization apparatus at a first temperature condition; and
c) applying a heat pulse which acts on a portion of the material to cause such portion of the material to vaporize and be applied to the substrate surface.

2. A method for vaporizing material onto a substrate surface to form a film, comprising:
a) providing a quantity of material into a vaporization apparatus;
b) heating the material in the vaporization apparatus at a first temperature condition; and
c) applying current to a heater that causes a heat pulse to be applied which acts on a portion of the material to cause such portion of the material to vaporize and be applied to the substrate surface.

3. A method for vaporizing organic material onto a substrate surface to form a film, comprising:
a) providing a quantity of organic material into a vaporization apparatus;
b) heating the organic material in the vaporization apparatus at a base temperature T_{b}; and
c) applying a heat pulse to cause a portion of the material to raise the temperature of such portion to a temperature Tᵥ which is greater than T_{b} and causes such material portion to vaporize and be applied onto the surface of the substrate.

4. A method for vaporizing organic material onto a substrate surface to form a film, comprising:
a) providing a quantity of organic material into a vaporization apparatus;
b) heating the organic material in the vaporization apparatus at a base temperature T_{b}; and
c) applying current to a heater that causes a heat pulse to be applied to cause a portion of the material to raise the temperature of such portion to a temperature Tᵥ which is greater than T_{b} and causes such material portion to vaporize and be applied onto the surface of the substrate.

5. The method according to claim 2 further including indexing the substrate above a defined deposition zone after the vapor flow from the heat pulse has subsided and applying another heat pulse to coat the next portion of the substrate.

6. The method according to claim 4 further including repeating the indexing and heat pulsing until the entire substrate has been coated uniformly.

7. The method according to claim 2 further including actively maintaining the material in a first heating region.

8. The method according to claim 2 further including metering the material into the vaporization apparatus.

9. The method according to claim 8 wherein the material metering step is related to the timing of the heat pulses.

10. The method according to claim 4 wherein the indexing of the substrate is related to the timing of the heat pulses.

11. A method for vaporizing organic material onto a substrate surface to form a film, comprising:
a) providing a quantity of organic material into a vaporization apparatus that includes a manifold with apertures through which vaporized material passes to coat the substrate;
b) heating the organic material in the vaporization apparatus at a base temperature T_{b}; and
c) applying current to a heater that causes a heat pulse to be applied which acts on a portion of the material to cause such portion of the material to raise the temperature of such portion to a temperature Tᵥ which is greater than T_{b} and causes such material portion to vaporize and pass through the apertures so as to be applied onto the surface of the substrate.

12. The method according to claim 11 further including applying an inert gas into the manifold to maintain conductance within the manifold.

13. The method according to claim 11 further including controlling the pulse height or pulse width.

14. The method according to claim 1 wherein the heat pulse is provided by a mechanical pulse of a material feed mechanism to bring material into sudden contact with a source of heat.

15. The method according to claim 3 wherein the heat pulse is provided by a mechanical pulse of a material feed mechanism to bring material into sudden contact with a source of heat.

16. The method according to claim 1 wherein the heat pulse is provided by a pulse of a material feed mechanism and a current pulse to the heater.

17. The method according to claim 3 wherein the heat pulse is provided by a pulse of a material feed mechanism and a current pulse to the heater.

18. The method according to claim 5 wherein the heat pulse is provided by mechanical pulse of a material feed mechanism to bring material into sudden contact with a source of heat.

19. The method according to claim 6 wherein the heat pulse is provided by a pulse of a material feed mechanism and a current pulse to the heater.

20. The method according to claim 11 wherein a plurality of materials is metered, each into its respective heating region where respective heat pulses are applied.

21. The method according to claim 20 wherein respective pulse heights or pulse widths for the plurality of materials are controlled to deposit the desired composition on the substrate.

22. The method according to claim 20 wherein respective pulse heights or pulse widths for the plurality of materials are controlled and sequenced to deposit the desired respective thicknesses on the substrate.

23. The method according to claim 20 wherein the heat pulses are provided by pulses of a material feed mechanism alone or in combination with current pulses to the heater.
